(19) United States
(12) Patent Application Publication
(10) Pub. No.: US 2014/0225592 A1
(43) Pub. Date: Aug. 14, 2014

(54) METHOD AND DEVICE FOR DETECTING ISOLATED OPERATION OF POWER GENERATION INSTALLATIONS

(71) Applicant: TECHNISCHE UNIVERSITAET CLAUSTHAL, Clausthal-Zellerfeld (DE)

(72) Inventors: Ralf Hesse, Wernigerode (DE); Dirk Turschner, Windhausen (DE); Hans-Peter Beck, Goslar (DE); Yong Chen, Clausthal-Zellerfeld (DE)

(21) Appl. No.: 14/345,961

(22) PCT Filed: Sep. 17, 2012
(86) PCT No.: PCT/EP2012/068243

§ 371 Date: Mar. 20, 2014

(30) Foreign Application Priority Data
Sep. 21, 2011 (DE) 10 2011 113 846.7

(51) Int. Cl. G01R 23/02; G01R 31/40

(52) U.S. Cl. CPC G01R 23/02; G01R 31/40
USPC 324/76.39

(57) ABSTRACT

The invention describes a method for detecting isolated operation of power generation instillations (5) which are set up to generate electrical power and can be coupled to an interconnected power supply system (1) for feed operation. The power generation installation (5) operates in isolation with respect M the interconnected power supply system when no power is exchanged between the power generation installation (5) and the interconnected power supply system (1). The method has the steps of; recording the temporal profile of the maims frequency present in the region in which the power generation installation (5) is connected to the interconnected power supply system (1) and evaluating the temporal profile of the mains frequency in order to detect isolated operation. Evaluating the temporal profile of the mains frequency comprises analysing the statistical features of the noise component of the temporal profile of the frequency of the mains voltage at the point at which the power generation installation (5) is connected to the interconnected power supply system (1), and isolated operation is detected using statistical behavioural features identified during analysis.

The invention relates to a method for detecting an island operating mode of energy generation plants, which are designed for generating electrical energy and can be coupled to an interconnected grid in the feed operating mode, wherein the energy generation plant operates in the island operating mode with respect to the interconnected grid when there is no energy exchange taking place between the energy generation plant and the interconnected grid, said method comprising the following steps:
detecting the time profile of the frequency of the mains voltage (mains frequency) which is present at the connection region between the energy generation plant and the interconnected grid, and
evaluating the time profile of the frequency of the mains voltage for detecting an island operating mode.

The invention furthermore relates to a device for detecting an island operating mode of energy generation plants, which are designed for generating electrical energy and can be coupled to an interconnected grid in the feed operating mode, wherein the energy generation plant operates in the island operating mode with respect to the interconnected grid and, in this case, no energy exchange takes place between the energy generation plant and the interconnected grid. The device has a mains frequency measuring unit that can be connected to the connection region between the energy generation plant and the interconnected grid for detecting the time profile of the mains frequency and an evaluation unit, which is connected to the mains frequency measuring unit.

In the event of decentralized feeding of electrical energy by decentralized stand-alone power systems, such as wind energy installations or solar power plants, into an interconnected grid, it is necessary for the operator of the interconnected grid to ensure that the permissible voltage and frequency limits are adhered to. In order to ensure safe operation of the interconnected grid, disconnection criteria are defined on the basis of a voltage measurement, a frequency measurement and an impedance measurement for identifying islanding. In this case, the identification of an undesired island operating mode of the stand-alone power system represents a problem.

Known solutions for identifying an unintentional island operating mode are subdivided into passive methods and active methods. In the passive methods, monitoring of the mains voltage in a temporal representation or a representation based on phasors and of the mains frequency in respect of sudden changes is provided. It is also possible for the harmonic content of the mains voltage to be taken into consideration, which is influenced by the relevant inverter. In the active methods, energy is transferred to the grid for test purposes. This enables determination of the mains impedance, which permits a conclusion to be drawn on the state of the electrical connection to the interconnected grid. In the active methods of mains voltage and mains frequency shifting, it is determined to what extent the mentioned mains parameters can be influenced by the effect of the feed inverter. The category of active methods also includes the pilot signal method, which envisages a radiofrequency signal being impressed on central grid points, which signal can be detected by the stand-alone power systems as evidence of the existing connection to the grid.

In addition to passive and active methods, also methods based on communication and information systems will be dealt with separately as well.

E. Handschin, E. Hauptmeier, W. Horenkamp, S. Malcher: “Inselnetzerkennung bei Eigenerzeugungsanlagen” [Island grid identification in stand-alone power systems], ETZ volume 12/2004, pages 48 to 50 describe measurement methods for island identification in stand-alone power systems with their advantages and disadvantages. In this case, the known methods for identifying grid impedances, the three-phase voltage monitoring, the voltage shift and frequency shift method and the pilot signal method are described.

N. Strath: “Island Detection in Power Systems”, in Licentiate Thesis, Lund University, Department of Industrial Electrical Engineering and Automation, 2005 describes passive methods for island identification by means of voltage measurement, frequency measurement, measurement of the rate of change of the frequency, the vector shift, the voltage fluctuation and the rate of change of the voltage and change in the power factor. That is to say that, for example, a comparison of the rate of change of the frequency at two locations in the grid is described as a passive method.

E. Rosolowski, A. Burek, L. Jedut: “A new method for islanding detection and distributed generation”, Wroclaw University of Technology, Poland, Eleco's 2007 5th International Conference of Electrical and Electronics Engineering disclose a method for identifying the island operating mode of a stand-alone power system by quasi-logic analysis of the three parameters, namely the change in voltage, the rate of change of the frequency and the rate of change of the active power.

H. H. Zeineldin, T. Abdel-Galil, E. F. El-Saadany, M. M. A. Salama: “Islanding detection of grid connected distributed generators using TLS-ESPRIT”, Electric Power Systems Research 77 (2007), pages 155-162 propose the use of the oscillation frequency and the damping factor of distributed stand-alone power systems as two parameters for island identification.

T. Pujhari: “Islanding detection in distributed generation”, Department of Electrical Engineering, National Institute of Technology, Rourkela, May 2009 proposes identification of the island operating mode with the aid of a wavelet transformation for monitoring the changes in parameters of interest, in particular the power spectrum.

The essential known methods for identifying island operating modes for stand-alone power systems are summarized in W. Bower, M. Ropp: “Evaluation of islanding detection methods for photovoltaic-utility interactive power systems, IEA PVPS International Energy Agency Implementing Agreement on Photovoltaic Power Systems, Task V Grid Interconnection of Building Integrated and other Dispersed Photovoltaic Power Systems, Report IEA PVPS T5-02:2002, March 2002.

The input of electrical energy for test purposes in the active methods has the disadvantage that, as a result, the quality of the mains voltage can be negatively influenced. The solutions based on communication and information systems require a relatively large amount of technical and financial expenditure. The known passive methods are only reliable to a limited extent since there is the difficulty of determining sufficiently precisely the status of the electrical connection to the interconnected grid from the changes in mains voltage and mains frequency over time determined. One problem also consists in that it is not possible to uniformly fix corresponding limit values. By virtue of the evaluation of sudden changes which take center stage in the passive methods, it is also not possible to draw a reliable conclusion in respect of the presence of an island operating mode.

Against this background, the object of the present invention consists in providing an improved method and a corresponding device for detecting an island operating mode of energy generation plants in order to be able to identify as easily and reliably as possible an island operating mode of an energy generation plant.

The object is achieved by the method having the features of claim 1 and the device having the features of claim 8.

By virtue of the evaluation of the time profile of the mains frequency by means of analysis of the statistical response of the noise signal of the time profile of the mains frequency and by detection of an island operating mode on the basis of statistical response features identified during the analysis, simple and reliable detection of the island operating mode of energy generation plants is achieved.

While until now only analysis of features of the time profile of the mains frequency has been performed for detection of an island operating mode, the present method provides an analysis of statistical properties of the time profile of the mains frequency, which is preferably detected in the form of individual values recorded in time-discrete fashion. It has been demonstrated that the presence of an interconnected grid is characterized by statistical features which can be isolated from the time profile of the mains frequency and preferably from the individual values of the mains frequency.

In an interconnected grid, a very large number of loads are connected or disconnected even in small time spans. However, the load-related change in frequency caused thereby in the interconnected grid no longer manifests itself in the form of resolvable decreases and increases which can be associated with the individual loads, but in the form of frequency noise. Noise phenomena are for their part subject to statistical laws which are used in the present method.

It is thus possible in a simple and reliable manner to detect an island operating mode.

The evaluation is preferably performed in time intervals of the time profile of the mains frequency, for example in cycles of 5 seconds.

Preferably, a determination of the statistical frequency distribution of the individual signal values of the noise component of the detected time profile of the mains frequency which is plotted over the frequency and a detection of an island operating mode in the case where a section of the profile of the determined statistical frequency distribution is found to be significantly outside a fixed range around the profile of a Gaussian normal distribution take place.

The frequency distribution of the individual signal values of the noise has detectable statistical peculiarities in the case of the presence of a connection to the interconnected grid. In the case of the presence of a connection to the interconnected grid, the frequency distribution of the discretely recorded values of the noise component of the measured mains frequency has a profile corresponding to the Gaussian frequency distribution or normal distribution with its characteristic values and the characteristic configuration. A connection of the stand-alone power system to the interconnected grid is therefore present when the Gaussian frequency distribution or normal distribution of the measured change in frequency of the voltage at the connection point of the stand-alone power system can be determined as being identifiable. If, on the other hand, there is no connection to the interconnected grid, frequency changes in the voltage at the connection point which are possibly caused in another way do not show the mentioned statistical features, with the result that it can then be concluded that there is an island operating mode.

Preferably, detection of the change in frequency in the voltage at the connection point of the energy generation plant to the interconnected grid and evaluation of this change in frequency as the time profile of the mains frequency take place.

It is particularly advantageous if the time profile of a virtual actual power of a simulated synchronous machine which is connected to the energy generation plant at the transition to the interconnected grid is detected. In this case, evaluation of the virtual active power is then performed as a measure of the time profile of the mains frequency. This has the advantage that the time profile of the mains frequency does not need to be measured electronically, but the virtual active power present as data stream of a synchronous machine simulated with the aid of a data processing system can be used in order to use the statistical response of the noise component of the time profile of the mains frequency or the virtual active power. If the simulated synchronous machine which is set up for the data processing system is equipped mathematically with a rotor which has an infinitely large moment of mass inertia, the virtual active power of the simulated synchronous machine directly follows all changes in the mains frequency, which means that the noise component of the time profile of the frequency of the mains voltage is transferred to the virtual active power of the simulated synchronous machine. It is thus possible to reproduce the change in a frequency variable and therefore the change in an alternating variable as a more easily detectable change in a DC variable. The method uses a simulated synchronous machine with an infinitely large moment of mass inertia as a particularly suitable frequency demodulator, therefore.

It is particularly advantageous if disconnection of the energy generation plant from the interconnected grid is performed for the case where an island operating mode has been detected. In this way, automatic, computer-controlled safeguarding of the interconnected grid at the feed point to a decentralized energy generation plant is also possible with relatively little complexity.

For this, the device has a mains switch (single-phase or polyphase), which is actuated by the evaluation unit by means of a control signal in order to switch over the mains switch for isolation of the energy generation plant from the interconnected grid when an island operating mode has been identified by the evaluation unit.

The evaluation unit of the device for detecting an island operating mode is preferably a data processing unit comprising a programmed processor (microprocessor, microcontroller, FPGA, ASIC etc.) suitable for implementing a method.

The invention will be explained in more detail below with reference to an exemplary embodiment with the attached drawings, in which:

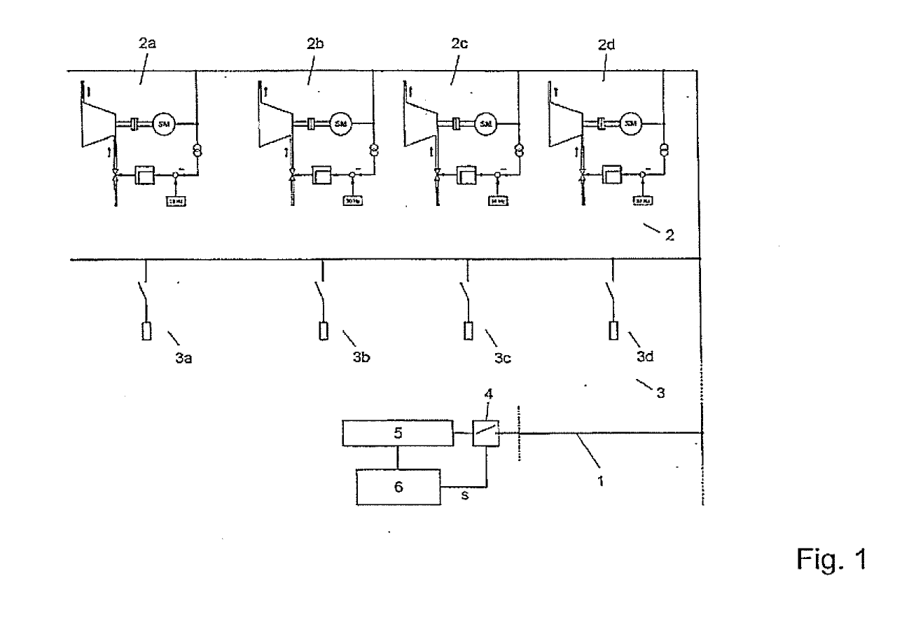

FIG. 1 shows a block diagram of the interface connection of a stand-alone power system into an electrical interconnected grid with a device for detecting an island operating mode and a grid disconnection apparatus;

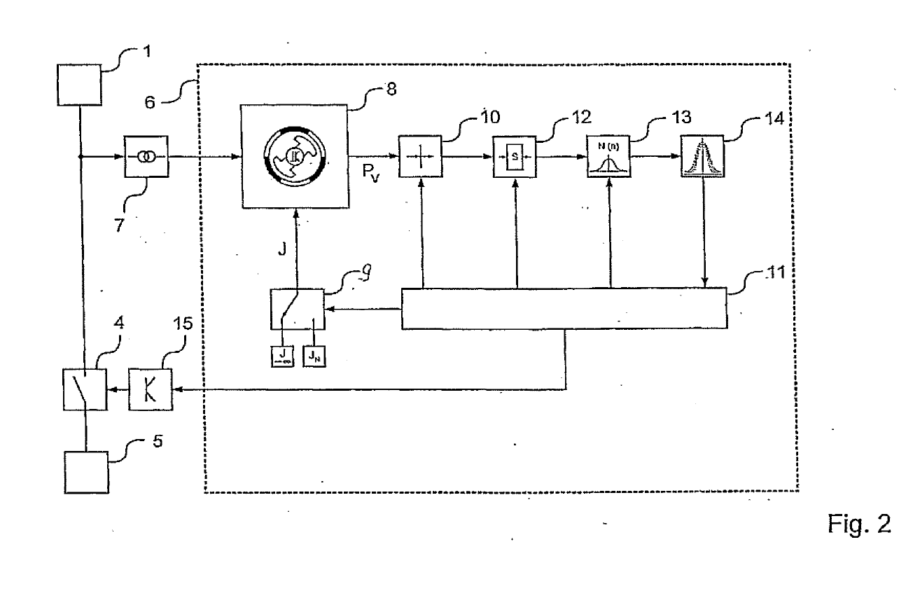

FIG. 2 shows a block circuit diagram of a device for detecting an island operating mode of energy generation plants.

FIG. 1 shows a sketch of an interconnected grid 1, to which a multiplicity of energy generation units 2a, 2b, 2c, 2d as energy generation unit group 2 and a multiplicity of loads 3a, 3b, 3c, 3d, referred to as load groups 3, are connected.

A (decentralized) stand-alone power system 5 is connected to the interconnected grid 1 via a disconnecting apparatus 4 in the form of a mains switch. Such a stand-alone power system may be, for example, a wind energy installation, a solar energy installation or the like.

A device 6 for detecting an island operating mode of the stand-alone power system 5 is connected to the stand-alone power system 5, preferably at the feed point of the stand-alone power system to the interconnected grid 1, which device is connected to a control signal S for the actuation of the disconnecting apparatus 4. In this way, the disconnecting apparatus 4 can be switched over with the aid of the control signal S and the stand-alone power system 5 can be disconnected from the interconnected grid 1 when the device detects an island operating mode of the stand-alone power system 5.

The detection of the island operating mode of the stand-alone power system 5 is based on the specifics of the variability of the mains frequency in interconnected grids 1. This variability of the mains frequency is brought about by the generator groups 2 and the load groups 3. The generator groups 2 of the interconnected grid 1 are operated with frequency regulation, as sketched, so as to maintain the mains frequency in the region of its setpoint value. The proportional regulation of the mains frequency by the individual power station units (generation units 2a, 2b, 2c, 2d) results, in principle, in remaining control errors, with the result that, in most cases, the precise setpoint value cannot be set. However, the size of the control error decreases with the number of grid-active power station units (generation units 2a, 2b, 2c, 2d) or with the level of the selected proportional factors.

Frequency deviations in the interconnected grid 1 are essentially determined by the response of the entirety of the load groups 3 installed in the grid unit. The connection of each individual load 3a, 3b, 3c, 3d always results in a decrease in frequency, even if this is infinitesimally small but proportional to the load, when the interconnected grid 1 is stationary at this time and no activity of other operating means can be recorded, in an interconnected grid 1 with generation units 2a, 2b, 2c, 2d which can be proportionally frequency-regulated. Since a very large number of loads is connected or disconnected in an interconnected grid 1 even in small time spans, the load-related change in frequency in the interconnected grid 1 no longer manifests itself in the form of resolvable decreases or increases which can be assigned to the individual loads 3a, 3b, 3c, 3d, but in the form of frequency noise. Noise phenomena for their part are subject to statistical laws which are used in the method for detecting an island operating mode and the corresponding device. In the case under consideration, this is the statistical distribution of the individual signal values of the noise component of the frequency of the mains voltage, the plotting of which reproduces the Gaussian frequency distribution or normal distribution with its characteristic values and the characterizing configuration. The Gaussian frequency distribution or normal distribution describes the distribution of a random variable, such as the frequency noise, in which the graphical representation of the probability density has the form of a bell curve, also referred to as a normal distribution curve. The normal distribution curve is symmetrical and has area components which are equal in size to the right and left of the central value. Most of the measured individual values describe, with their frequencies, the central region of the normal distribution curve.

For the technical evaluation of the noise, it is furthermore essential that the frequency noise and not the amplitude noise of the recorded signal at the connection of the stand-alone power system 5 to the interconnected grid is used for the further processing. This is based on an insensitivity with respect to changes in amplitude. A comparable insensitivity of the method for detecting an island operating mode, with respect to changes in mains frequency, consists in timescales with typical diurnal variations when correspondingly small time intervals of the time profile of the mains frequency are evaluated.

The device 6 for identifying the island operating mode is designed to evaluate the time profile of the mains frequency by analysis of the statistical properties of the noise component of the time profile of the mains frequency and to detect an island operating mode on the basis of statistical features identified during the analysis. This can take place in the preferred exemplary embodiment described by virtue of the fact that an interconnected grid operating mode, i.e. no island operating mode, is present when, in accordance with the guidelines in respect of the disconnection of stand-alone power systems 5, in order to avoid unintentional island operating mode in cycles of 5 seconds in each case the Gaussian frequency distribution or normal distribution can be determined identifiably from the set of changes in frequency of the voltage at the connection point of the stand-alone power system 5 to the interconnected grid 1 which are measured discretely in these time segments. If, on the other hand, there is no connection to the interconnected grid 1, changes in the frequency of the voltage at the connection point which are possibly caused in other ways do not demonstrate the mentioned statistical features and therefore a shape of the frequency distribution which significantly deviates from the profile shape of the Gaussian frequency distribution or normal distribution, and the disconnecting apparatus 4 of the stand-alone power system 5 is actuated as a result of the detection of an island operating mode by the device 6.

FIG. 2 shows a block diagram of such a device 6 for detecting an island operating mode, which device, with the aid of a control signal S, actuates a disconnecting apparatus 4 between the stand-alone power system 5 and the interconnected grid 1 when an island operating mode has been detected. For this, the disconnecting apparatus 4 in the form of a grid safety disconnection switch for disconnecting the stand-alone power system 5 in the event of an unintentional island operating mode is provided between the stand-alone power system 5 and the interconnected grid 1.

In order to detect the time profile of the mains frequency, a potential-isolating mains voltage converter 7 is connected to the interconnected grid downstream of the disconnecting apparatus 4, when viewed from the stand-alone supply system 5 in the direction of the interconnected grid. This potential-isolating mains voltage converter 7 feeds the voltage/time profile of the three-phase mains voltage recorded at its connection point to the device 6 for detecting an island operating mode. This device 6 is preferably in the form of a data processing unit and, by suitable programming, is designed for evaluating the time profile of the mains frequency and detecting an island operating mode. However, it is also conceivable for the device 6 to be formed from correspondingly specialized signal processing units.

The algorithmic components described below are implemented in the device 6.

The recorded mains voltage signal is supplied to a computation model of a virtual synchronous machine 8, as is described in DE 10 2006 047 792 A1, for example. The virtual moment of mass inertia of the virtual synchronous machine 8 can be alternated, via a switchover device 9, between the rated value of the machine model J=J_{N} and an infinitely large moment of mass inertia J=→∞. The virtual active power Pᵥ which is guided to a gate 10 is present at the output of the virtual synchronous machine 8. The output of the gate 10, which is actuated via a sequence controller 11, is connected to the measured value store 12, which is likewise actuated by the sequence controller 11. The evaluation unit 13 for the statistical evaluation of the recorded time profile of the virtual active power Pᵥ, which is proportional to the time profile of the mains frequency, is connected and set up downstream of the measurement store 12 and is likewise actuated by the sequence controller 11. The pattern comparison function 14, whose output is supplied to the sequence controller 11, is connected downstream of the evaluation unit 13.

The sequence controller 11 erases the measured value store 12 prior to the beginning of each 5-second measurement period in the case of a previously blocked gate 10, while the virtual moment of mass inertia of the virtual synchronous machine 8 is set to the value J=J_{N} by virtue of the switchover 9 in order to relieve the virtual rotor of the virtual synchronous machine 8 of load. A measurement interval begins with the opening of the gate 10 and the switchover of the virtual moment of mass inertia to the value J=→∞). Within the duration specified in the guidelines for disconnection of stand-alone power systems 5 of 5 seconds, the values for the virtual active power Pᵥ of the virtual synchronous machine 8 which are determined in time-discrete fashion are recorded in the measured value store 12. In this phase, every even very small change in the mains frequency results in an angular displacement in the model of the virtual synchronous machine 8 since the speed of said machine cannot change owing to the infinitely large virtual mass J. At the end of each measurement phase, first the gate 10 is blocked and the virtual moment of mass inertia J is reset to the rated value J=J_{N}. The frequency distribution is determined directly from the interpolation points of the virtual active power Pᵥ on the basis of a statistical function in the evaluation unit 13 from the discrete values for the virtual active power Pᵥ which are recorded in the measured value store 12. If there is an electrical connection to the interconnected grid 1, the profile of the frequency distribution corresponds to that of the Gaussian frequency distribution or the normal distribution. With the aid of a pattern comparison function 14, the profile shape of the determined frequency distribution is validated taking into consideration permissible deviations and with the formation of a switching command for actuating the disconnecting apparatus 4 via a switching amplifier 15 in order to implement the grid disconnection of the stand-alone power system 5 from the interconnected grid 1 for the case where the profile shape of the determined frequency distribution of the discrete values for the virtual active power Pᵥ substantially deviates from the profile shape of a typical Gaussian frequency distribution or normal distribution. After implementing the comparison of the profile shape of the frequency distribution of the discrete values of the virtual active power Pᵥ with the typical (stored) profile shape of the Gaussian frequency distribution or the normal distribution, the sequence controller 11 begins a new measurement cycle. Measurement cycles of any desired number are implemented successively without any breaks for the continuous monitoring of the grid in respect of an island operating mode.

1. A method for detecting an island operating mode of energy generation plants, which are designed for generating electrical energy and can be coupled to an interconnected grid in the feed operating mode, wherein the energy generation plant operates in the island operating mode with respect to the interconnected grid when there is no energy exchange taking place between the energy generation plant and the interconnected grid, said method comprising the following steps:
detecting the time profile of the frequency of the mains voltage which is present at the connection region between the energy generation plant (5) and the interconnected grid (1), and
evaluating the time profile of the frequency of the mains voltage for detecting an island operating mode,
wherein the evaluation of the time profile of the frequency of the mains voltage comprises an analysis of the statistical properties of the noise component of the time profile of the frequency of the mains voltage and detection of an island operating mode on the basis of statistical identification features identified during the analysis.

2. The method as claimed in claim 1, characterized by evaluation of time intervals of the time profile of the frequency of the mains voltage.

3. The method as claimed in claim 1, characterized by determination of the frequency distribution of the discretely recorded individual signal values of a noise component of the detected time profile of the frequency of the mains voltage over the frequency and detection of an island operating mode in the case where the thus determined frequency distribution does not fall within a tolerance band about a predetermined frequency distribution.

4. The method as claimed in claim 3, wherein the predetermined frequency distribution is a Gaussian frequency distribution.

5. The method as claimed in claim 1, characterized by detection of the change in the frequency of the mains voltage at the connection point between the energy generation plant and the interconnected grid and evaluation of these changes in the frequency of the mains voltage.

6. The method as claimed in claim 1, characterized by time-discrete detection of the profile of the virtual active power of a simulated synchronous machine, which is coupled to the energy generation plant at the transition to the interconnected grid, and evaluation of the set of time-discrete measured values of the virtual active power (Pv) as a measure of the time profile of the frequency of the mains voltage.

7. The method as claimed in claim 1, characterized by disconnection of the energy generation plant from the interconnected grid in the case where an island operating mode has been detected.

8. A device for detecting an island operating mode of energy generation plants, which are designed for generating electrical energy and can be coupled to an interconnected grid in the feed operating mode, wherein the energy generation plant operates in the island operating mode with respect to the interconnected grid and, in this case, no energy exchange takes place between the energy generation plant and the interconnection grid, wherein the device has a frequency measuring unit that can be connected to the connection region between the energy generation plant and the interconnected grid for detecting the time profile of the frequency of the mains voltage and an evaluation unit, which is connected to the frequency measuring unit,
wherein the evaluation unit is designed to analyze the statistical features of the noise component of the time profile of the frequency of the mains voltage and to detect an island operating mode on the basis of statistical identification features identified in the analysis.

9. The device as claimed in claim 8, wherein the device has at least one disconnecting apparatus that can be actuated by the evaluation unit and the sequence controller and is designed in such a way that the disconnecting apparatus disconnects the energy generation plant from the interconnected grid (1) on detection of an island operating mode by the evaluation unit by means of a switching signal of the evaluation unit.

10. The device as claimed in claim 8, wherein the evaluation unit is designed for implementing the method having the features of claims 2 to 6.
